(19) United States
(12) Patent Application Publication
(10) Pub. No.: US 2011/0013192 A1
(43) Pub. Date: Jan. 20, 2011

(54) LOCALIZED SURFACE PLASMON RESONANCE SENSOR AND FABRICATION METHOD THEREOF

(75) Inventors: Chih-Chung Yang, Taipei City (TW); Cheng-Yen Chen, Taipei City (TW); Jyh-Yang Wang, Taipei City (TW); Yen-Cheng Lu, Taipei City (TW); Hung-Yu Tseng, Taipei City (TW); Fu-Ji Tsai, Taipei City (TW)

Correspondence Address: QUINTERO LAW OFFICE, PC, 615 Hampton Dr, Suite A202, Venice, CA, 90291, US

(73) Assignee: NATIONAL TAIWAN UNIVERSITY, TAIPEI (TW)

(21) Appl. No.: 12/698,076

(22) Filed: Feb. 1, 2010

(30) Foreign Application Priority Data
Jul. 16, 2009 (TW) TW098124051

(51) Int. Cl. G01N 21/55; H01L 31/18

(52) U.S. Cl. 356/445; 438/63; 977/773; 257/E31.11

(57) ABSTRACT

A method for forming a localized surface plasmon resonance (LSPR) sensor is disclosed, including providing a substrate, forming a metal thin film on the substrate and irradiating the metal thin film with a laser to form a plurality of metal nanoparticles, wherein the metal nanoparticles have a fixed orientation.

### CROSS REFERENCE

This Application claims priority of Taiwan Patent Application No. 098124051, filed on Jul. 16, 2009, the entirety of which is incorporated by reference herein.

### BACKGROUND OF THE INVENTION

1. Field of the Invention

The invention relates to a method for forming a metal nanostructure and more particularly relates to a method for forming a localized surface plasmon resonance sensor.

2. Description of the Related Art

Metal nanostructures are widely used in fabricating gas sensors, biochemical sensors and nano wave guides due to its special physical and chemical characteristics. When a metal nanostructure is applied with an electromagnetic field, electrons collectively oscillate with a specific frequency corresponding to the incident light to generate resonance. This phenomenon is called localized surface plasmon resonance (LSPR), which is different from surface plasmon polariton on a metal surface. LSPR wavelength of a metal nanostructure varies according to type of the metal material, size of the metal structure, shape of the metal structure and the environment. A metal nanostructure can therefore be used for bio-sensing due to the sensitive LSPR wavelength dependence on the surrounding medium.

Chemical synthesis methods are generally used for fabricating metal nanoparticles, which are spin-coated on a substrate for bio-sensing application. However, metal nanoparticles spin-coated on a substrate do not strongly bond to the substrate such that the sensing measurement becomes unstable. Also, metal nanoparticles on the substrate may aggregate to reduce the sensitivity of sensing measurement. Further, the spin-coated metal nanoparticles on the substrate normally have random orientations leading to lower sensing sensitivity.

### BRIEF SUMMARY OF INVENTION

The invention provides a method for forming a localized surface plasmon resonance (LSPR) sensor, comprising providing a substrate, forming a metal thin film on the substrate and irradiating the metal thin film with a laser to form a plurality of metal nanoparticles.

The invention provides a localized surface plasmon resonance (LSPR) sensor, comprising a substrate, and a plurality of metal nanoparticles on the substrate, wherein the metal nanoparticles have a fixed orientation and are directly bonded to the substrate.

The invention provides a method for forming a metal nanostructure, comprising providing a substrate, forming a metal thin film on the substrate and irradiating the metal thin film with a laser to form a plurality of metal nanoparticles, wherein the metal nanoparticles have a fixed orientation.

### BRIEF DESCRIPTION OF DRAWINGS

The invention can be more fully understood by reading the subsequent detailed description and examples with references made to the accompanying drawings, wherein:

FIGS. 1A˜1C illustrate a method for forming a metal nanostructure of an embodiment of the invention.

FIG. 2 shows the transmission spectra of the Au nanoparticle samples on sapphire substrate and silicon oxide template with the s and p incident polarization conditions.

FIG. 3 shows a scanning electron microscope (SEM) picture of an Au thin film not irradiated by the laser.

FIG. 4 shows Au nanoparticles formed by a method of an embodiment of the invention.

FIG. 5 shows a scanning electron microscope (SEM) picture which shows the cut-facets of sphere-like Au nanoparticles.

FIG. 6 shows Au nanoparticles formed by a method of another embodiment of the invention.

FIG. 7 shows Au nanoparticles formed by a method of another embodiment of the invention.

FIG. 8 shows Au nanoparticles formed by a method of yet another embodiment of the invention.

### DETAILED DESCRIPTION OF INVENTION

Embodiments of the invention are illustrated in the following paragraph. The embodiments are used to describe characteristics of the invention but do not limit the invention.

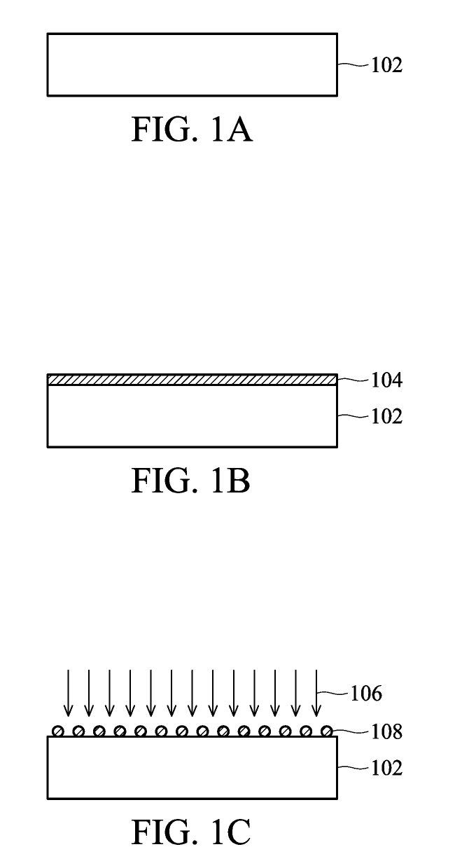

Referring to FIG. 1A, a substrate 102 is provided. In an embodiment of the invention, the substrate 102 can be made of sapphire, glass or GaN. In addition, a dielectric thin film (not shown), such as silicon oxide, can be formed on a surface of the substrate 102. Next, referring to FIG. 1B, a metal thin film 104 is formed on the substrate 102 or the dielectric thin film on the substrate 102. The metal thin film can be formed by electron-beam evaporation or sputtering process. The metal thin film preferably is made of noble metal, such as Au, Ag, Cu or Al. For example, when the metal thin film is Au, the preferable thickness is about 5 nm˜20 nm. Referring to FIG. 1C, the metal thin film 104 is irradiated by a laser 106 for the metal thin film 104 to become a melting state and when the melting metal solidifies, a plurality of nanoparticles 108 with substantially round shapes are formed due to surface tension. In the embodiment, the laser is a four multiple frequency of a Nd-YAG laser with wave length of 266 nm. It is noted that the nanoparticles formed by the method of the embodiment have fixed orientation, directly bonded to the substrate and have good adhesion with the substrate. Due to the fixed orientation of the nanoparticles, a clear out-of-plane and in-plane localized surface plasmon resonance (LSPR) feature in the transmission spectrum are formed for improving LSPR sensing sensitivity.

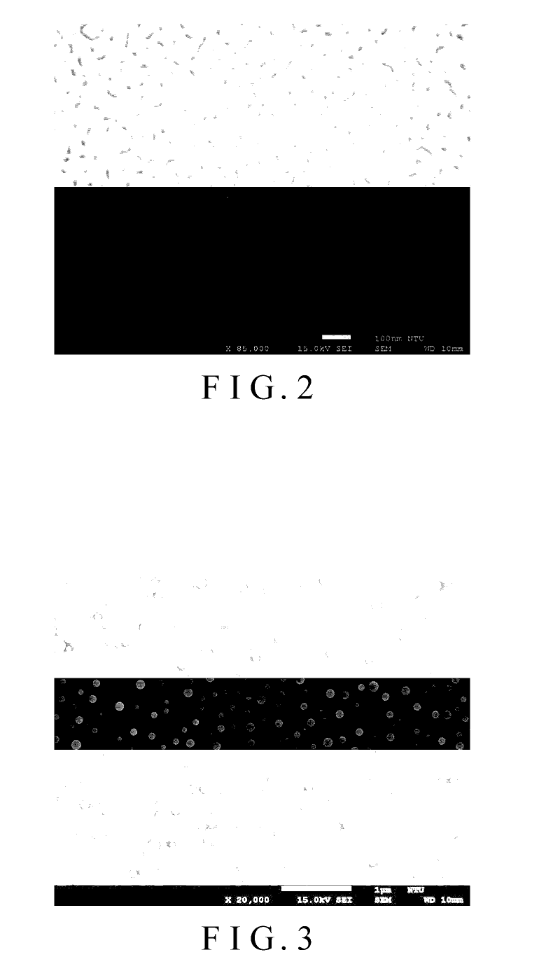

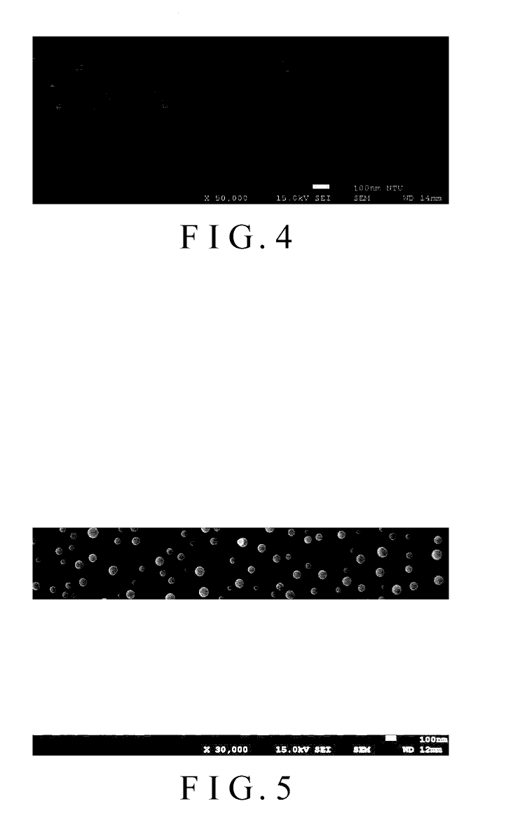

The following paragraph illustrates a method for forming a gold nano-particle of an example of the invention. First, a sapphire substrate is provided. A gold thin film with thickness of about 10 nm is deposited on the sapphire substrate. A laser with pulse energy density of about 30 mJ/cm² is provided and the gold thin film is irradiated by the laser. FIG. 2˜FIG. 4 show scanning electron microscope (SEM) pictures of an embodiment of the invention. FIG. 2 shows the gold thin film not irradiated by the laser. As shown in FIG. 2, nanoparticles are not formed on the substrate when the gold thin film is not irradiated by the laser. FIG. 3 shows the gold thin film irradiated by the laser. As shown in FIG. 3, nanoparticles are formed on the substrate. FIG. 4 shows a scanning electron microscope (SEM) picture which shows the cut-facet of sphere-shaped nanoparticles.

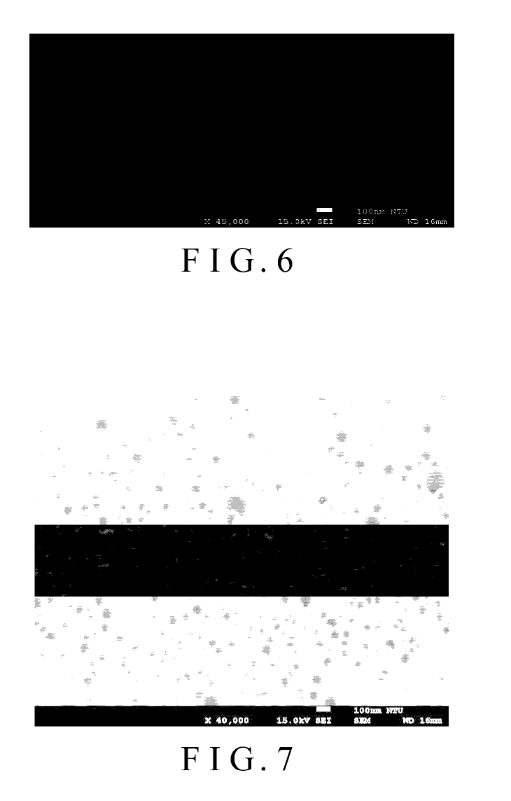

A method for forming gold nanoparticles of another example of the invention is illustrated. First, a sapphire substrate is provided. A GaN layer is formed on the sapphire substrate by an MOCVD process, wherein the deposited temperature is about 1000° C. and thickness of the GaN layer is about 2 μm. A gold thin film with thickness of about 7.5 nm is deposited on the sapphire substrate. A laser with pulse energy density of about 20 mJ/cm² is provided and the gold thin film is irradiated by the laser. FIG. 5 and FIG. 6 show scanning electron microscope (SEM) pictures of the embodiment of the invention. The nanoparticles have diameters of about 40 nm—120 nm, an average diameter of about 75 nm and contact angle of cut-facet of about 130°.

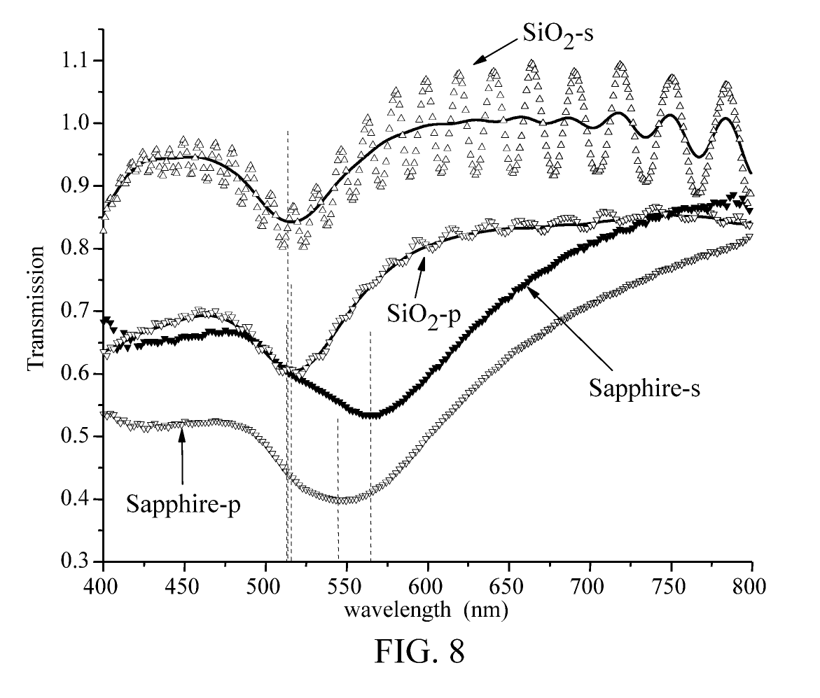

A method for forming gold nanoparticles of further another example of the invention is illustrated. First, a GaN layer is provided. A silicon oxide layer is formed on the sapphire substrate by a PECVD process, wherein thickness of the silicon oxide layer is about 30 nm. A gold thin film is deposited on the silicon oxide layer. A laser is provided and the gold thin film is irradiated by the laser. FIG. 7 shows a scanning electron microscope (SEM) picture of the embodiment of the invention. The nanoparticles shown in FIG. 8 have greater diameters and the contact angle of cut-facet is about 180°.

Table 1 shows parameters of methods for forming nanoparticles with laser irradiation of examples of the invention.

TABLE 1

| Substrate | sapphire | sapphire | sapphire | GaN | SiO₂ |
|---|---|---|---|---|---|
| Au thickness (nm) | 10 | 10 | 10 | 7.5 | 10 |
| Laser energy | 30 | 30 | 30 | 20 | 20 |
| density (mJ/cm²) | | | | | |
| Number of pulses | 2 | 2 | 2 | 5 | 1 |
| Covering gas/liquid | air | water | methanol | air | air |
| Average NP diameter (nm) | 91.3 | 92.5 | 97.9 | 77.9 | 37.4 |
| Estimated contact angle | 138 | >145 | >145 | <130 | ~180 |
| NP density (cm⁻²) | 1.75 × 10⁹ | 1.25 × 10⁹ | 1.02 × 10⁹ | 2.78 × 10⁹ | 1.29 × 10¹⁰ |
| Surface coverage (%) | 13.18 | 12.8 | 10.6 | 14.04 | 17.7 |

Nanoparticles formed by methods of the embodiments described are measured to detect localized surface plasmon resonance (LSPR). The substrate with nanoparticles is irradiated by a white light and a measurement at the backside of the substrate is performed to check the transmission and the localized surface plasmon resonance wavelength. FIG. 2 shows the transmission spectra of the Au nanoparticle samples on the GaN and silicon oxide with the s and p incident polarization conditions when the incident angle is 60 degrees with respect to the normal of the substrate surface. In the example, the gold thin film has a thickness of 10 nm, the laser energy density is 30 mJ/cm², and the pulse number is two for the sample on a sapphire substrate and is one for the sample on a silicon oxide template. The gold thin film is surrounded by air. As shown in FIG. 8, the curve has dips at the wavelengths of 515 nm and 565 nm. Thus, the LSPR has lower transmission frequency at 515 nm and 565 nm. The test clearly shows lower points of transmission wavelengths. Thus, the nanoparticles measured have fixed orientation. In addition, transmission behaviors are different when the metal material, diameter, contact angle, surface density and/or surface coverage ratio of the nanoparticles are varied. These parameters can be changed by adjusting thickness of the thin film, laser energy density, and ambience of the disposed nanoparticles and the change shows different transmission spectra. For example, the contact angle of the nanoparticles is related to the substrate material and the metal melting temperature.

Accordingly, the invention can form nanoparticles with a fixed orientation bonded to a substrate. The nanoparticles have clear localized surface plasmon resonance (LSPR). The nanoparticles formed by the method of the invention can be used to form a localized surface plasmon resonance (LSPR) sensor to sense change of ambience according to change of resonance curves. For example, the localized surface plasmon resonance frequency changes with variation of the refractive index of a liquid that contacts the LSPR sensor. Therefore, variation of refractive index of the liquid can be obtained by checking the wavelength of the localized surface plasmon resonance.

While the invention has been described by way of example and in terms of the preferred embodiments, it is to be understood that the invention is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a localized surface plasmon resonance (LSPR) sensor, comprising:
providing a substrate;
forming a metal thin film on the substrate; and
irradiating the metal thin film with a laser to form a plurality of metal nanoparticles.

2. The method for forming a localized surface plasmon resonance sensor as claimed in claim 1, wherein the metal nanoparticles are directly bonded to the substrate.

3. The method for forming a localized surface plasmon resonance sensor as claimed in claim 1, wherein the metal nanoparticles have a fixed orientation.

4. The method for forming a localized surface plasmon resonance sensor as claimed in claim 1, wherein the metal thin film is formed of Au, Ag, Cu or Al.

5. The method for forming a localized surface plasmon resonance sensor as claimed in claim 1, wherein the substrate is sapphire, glass, semiconductor material such as GaN or dielectric material such as silicon oxide.

6. The method for forming a localized surface plasmon resonance sensor as claimed in claim 1, wherein the substrate further comprises a dielectric layer formed thereon.

7. The method for forming a localized surface plasmon resonance sensor as claimed in claim 6, wherein the dielectric layer is glass or silicon oxide.

8. The method for forming a localized surface plasmon resonance sensor as claimed in claim 1, wherein the metal nanoparticles have clear out-of-plane and in-plane localized surface plasmon resonance.

9. The method for forming a localized surface plasmon resonance sensor as claimed in claim 1, wherein thickness of the metal thin film, energy density of the laser, material of the substrate, and ambience of the metal nanoparticles located can be adjusted for the localized surface plasmon resonance sensor to show different LSPR wavelengths.

10. A localized surface plasmon resonance (LSPR) sensor, comprising:
a substrate; and
a plurality of metal nanoparticles on the substrate, wherein the metal nanoparticles have a fixed orientation and are directly bonded to the substrate.

11. The localized surface plasmon resonance (LSPR) sensor as claimed in claim 10, wherein the metal nanoparticles are formed of Au, Ag, Cu or Al.

12. The localized surface plasmon resonance (LSPR) sensor as claimed in claim 10, wherein the substrate is sapphire, glass, semiconductor material such as GaN or dielectric material such as silicon oxide.

13. The localized surface plasmon resonance (LSPR) sensor as claimed in claim 10, wherein the substrate further comprises a dielectric layer formed thereon.

14. The localized surface plasmon resonance (LSPR) sensor as claimed in claim 13, wherein the dielectric layer is glass or silicon oxide.

15. The localized surface plasmon resonance (LSPR) sensor as claimed in claim 10, wherein thickness of the metal thin film and energy density of a laser to form the metal nanoparticles, material of the substrate, and ambience of the metal nanoparticles located can be adjusted for the localized surface plasmon resonance sensor to show different LSPR wavelengths.

16. A method for forming a metal nanostructure, comprising:
providing a substrate;
forming a metal thin film on the substrate; and
irradiating the metal thin film with a laser to form a plurality of metal nanoparticles, wherein the metal nanoparticles have a fixed orientation.

17. The method for forming a metal nanostructure as claimed in claim 16, wherein the substrate is sapphire, glass, semiconductor material such as GaN or dielectric material such as silicon oxide.

18. The method for forming a metal nanostructure as claimed in claim 16, wherein the substrate further comprises a dielectric layer formed thereon.

19. The method for forming a metal nanostructure as claimed in claim 18, wherein the dielectric layer is glass or silicon oxide.

20. The method for forming a metal nanostructure as claimed in claim 16, wherein the metal nanoparticles have clear out-of-plane and in-plane localized surface plasmon resonance.
